(19) United States
(12) Patent Application Publication
(10) Pub. No.: US 2024/0172507 A1
(43) Pub. Date: May 23, 2024

(54) DISPLAY DEVICE

(71) Applicant: LG Display Co., Ltd., Seoul (KR)

(72) Inventors: Myeong Su KIM, Paju-si (KR); Chang Duk HA, Paju-si (KR); Dong Kyu KIM, Paju-si (KR)

(73) Assignee: LG Display Co., Ltd., Seoul (KR)

(21) Appl. No.: 18/514,752

(22) Filed: Nov. 20, 2023

(30) Foreign Application Priority Data
Nov. 22, 2022 (KR) 10-2022-0157122

(51) Int. Cl. H10K 59/131; H10K 59/124

(52) U.S. Cl. CPC H10K 59/131; H10K 59/124

(57) ABSTRACT

A display device includes a substrate including a display area, a non-display area extended from the display area, and a bending area included in the non-display area, a plurality of wirings formed in the bending area, and a micro cover layer formed on the plurality of wirings. A groove is formed in the substrate to be overlapped with the micro cover layer.

### CROSS-REFERENCE TO RELATED APPLICATION

This application claims priority to Korean Patent Application No. 10-2022-0157122, filed in the Republic of Korea on Nov. 22, 2022, the entire disclosure of which is hereby expressly incorporated by reference into the present application.

### BACKGROUND

### 1. Technical Field

The present disclosure relates to a display device. In detail, the present disclosure relates to a display device prepared for preventing or reducing damage to wirings by stresses due to bending or loads applied to a bending area.

### 2. Discussion of Related Art

Recently, the relevance of a display device as a visual information transmission medium has been further emphasized in the information society, and in order to remain relevant in the future, the display device needs to satisfy certain needs such as low power consuming, thinning, weight lightening, high defining, and the like.

Display devices are classified into a light emitting type such as cathode ray tubes (CRT), electro luminescence (EL), light emitting diodes (LED), vacuum fluorescent displays (VFD), field emission displays (FED), and plasma display panels (PDP) that emit light by themselves, and a non-emitting type such as liquid crystal displays that do not emit light themselves.

In the display device, at least a portion of the display device can be bent, such that visibility from various angles can be improved or the area of the non-display area can be reduced.

The description provided in the background section should not be assumed to be prior art merely because it is mentioned in or associated with the background section. The background section can include information that describes one or more aspects of the subject technology.

### SUMMARY OF THE DISCLOSURE

It is newly recognized by inventors of the present disclosure that, the display device of which at least a portion of the display device is bent is subjected to stresses due to bending, and the stresses are concentrated in the bending area. Accordingly, there is a limitation that reliability and stability can be deteriorated or lowered due to disconnection or cracks occurring in wirings disposed in a bending area where stresses can be concentrated. In detail, if a crack is generated in the bending area by an external force, the crack can be propagated by the bending to cause the disconnection or crack of the wiring. Alternatively, if the stresses are concentrated on the wirings due to the bending, the possibility of disconnection or crack of the wirings can be increased due to the stresses. Thus, there is a demand for a structurally improved display device to prevent or reduce damage due to external force while reducing the stresses applied to the wirings.

Accordingly, the present disclosure is directed to a display device that substantially obviates one or more of the issues due to limitations and disadvantages of the related art.

An aspect of the present disclosure is to provide a display device that minimizes or reduces stresses applied to wirings in a bending area and prevents or reduces damage to the wirings due to external force by using a groove formed on a substrate of the bending area.

Additional features and aspects of the present disclosure are set forth in part in the description that follows and in part will become apparent from the description or can be learned by practice of the inventive concepts provided herein. Other features and aspects of the inventive concepts can be realized and attained by the structures pointed out in the present disclosure, or derivable therefrom, and the claims hereof as well as the appended drawings.

To achieve these and other aspects of the inventive concepts, as embodied and broadly described herein, a display device according to embodiments of the present specification can include a substrate including a display area, a non-display area extended from the display area, and a bending area included in the non-display area, a plurality of wirings formed on (in) the bending area, and a micro cover layer formed on the plurality of wirings, wherein a groove can be formed on the substrate to be overlapped with the bending area.

A display device according to embodiments of the present specification can include a substrate including a display area, a non-display area extended from the display area, and a bending area included in the non-display area; a plurality of wirings formed on (in) the bending area, and a groove formed on the substrate to be overlapped with the bending area, wherein a neutral plane of the bending area can be positioned close to the center of the wiring by the groove disposed to be overlapped with a partial area of the wiring

In the embodiments according to the present specification, the groove formed on the substrate of the bending area is used and thus the neutral plane in the bending area is moved toward the wiring, such that stresses applied to the wirings due to bending can be minimized or reduced.

In the embodiments according to the present specification, the stresses applied to wirings are minimized or reduced and thus lifetime can be improved, such that low-power driving can be allowed in terms of production energy reduction.

Various useful advantages and effects of the embodiments are not limited to the above-described contents, and other effects, which are not described above, will be clearly understood by those skilled in the art from the following description.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that can be included to provide a further understanding of the disclosure and can be incorporated in and constitute a part of the disclosure, illustrate embodiments of the disclosure and together with the description serve to explain various principles of the disclosure. The above and other objects, features, and advantages of the embodiments of the present specification will become more apparent to those of ordinary skill in the art by describing the embodiments thereof in detail with reference to the attached drawings, in which:

FIG. 1 is a perspective view illustrating a display device according to an example embodiment of the present specification;

FIG. 2 is a cross-sectional view illustrating a bent state of the display device according to an example embodiment of the present specification;

FIG. 3 is a plan view illustrating a display device according to an example embodiment of the present specification;

FIGS. 4 and 5 are views illustrating various examples in which a display panel of a display device according to an example embodiment of the present specification is bent;

FIGS. 6 to 8 are circuit diagrams illustrating various pixel circuits applicable to a display area of a display device according to an example embodiment of the present specification;

FIG. 9 is a waveform diagram illustrating a driving signal applied to the pixel circuit shown in FIG. 8 according to an example embodiment of the present specification;

FIG. 10 is a cross-sectional view schematically illustrating a cross-sectional structure of a display area of a display device according to an example embodiment of the present specification;

FIG. 11 is a cross-sectional view schematically illustrating a cross-sectional structure of a display area of a display device according to another example embodiment of the present specification;

FIG. 12 is a cross-sectional view schematically illustrating a cross-sectional structure of a display area of a display device according to still another example embodiment of the present specification;

FIG. 13 is a diagram illustrating a neutral plane depending on a bending in a bending area of a display device according to an example embodiment of the present specification;

FIG. 14 is a diagram illustrating a manufacturing process of a substrate formed including a groove according to an example embodiment of the present specification;

FIG. 15 is a diagram illustrating a cross-sectional structure of a display area in a display device according to an example embodiment of the present specification;

FIG. 16 is a schematic diagram illustrating a movement of a neutral plane in a bending area of a display device according to an example embodiment of the present specification; and

FIG. 17 is a diagram illustrating a cross-sectional structure of a display area in a display device according to another example embodiment of the present specification.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

The advantages and features of the present disclosure and methods for accomplishing the same will be more clearly understood from example embodiments described below with reference to the accompanying drawings. However, the present disclosure is not limited to the following example embodiments but can be implemented in various different forms. Rather, these example embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the various example embodiments of the present disclosure are exemplary, and the present disclosure is not limited to the illustrated items. Like reference numerals refer to like elements throughout. In addition, in describing the present disclosure, if it is determined that the detailed description of the related known technology can unnecessarily obscure the subject matter of the present disclosure, the detailed description thereof will be omitted or can be briefly provided. Any implementation described herein as an “example” is not necessarily to be construed as preferred or advantageous over other implementations.

When “include”, “have”, “consist”, or the like mentioned in the present specification, other parts can be added unless terms such as “only” is used. In the case where the component is expressed in the singular, the plural includes the plural unless specifically stated otherwise.

In interpreting a component, it is interpreted to include an error range or tolerance range even if there is no separate description of such an error or tolerance range.

In the case of the description of the positional relationship, for example, if the positional relationship of the two parts is described as “on the top”, “on the top”, “on the bottom”, “next to”, etc., one or more other parts can be located between the two parts unless the term such as “directly”, “closely” or “immediately” is explicitly used. Furthermore, the terms “left,” “right,” “top,” “bottom, “downward,” “upward,” “upper,” “lower,” and the like refer to an arbitrary frame of reference.

In describing a time relationship, for example, when the temporal order is described as for example, “after,” “subsequent,” “next,” and “before,” a case which is not continuous can be included unless a more limiting term, such as “just,” “immediate(ly),” or “direct(ly)” is used.

In the description for the embodiments, the first, second, “A,” “B,” “(a),” and “(b),” etc. are used to describe various components, but these components are not limited by these terms, and the essence, sequence, order, or number of the corresponding elements should not be limited by these terms. These terms are only used to distinguish one component from another. Therefore, the first component mentioned below can be a second component within the technical idea of the present disclosure.

Throughout the specification, the same reference numerals refer to the same component.

Where an element or layer is referred to as being “on,” “above,” “over,” or “connected to” another element or layer, it should be understood to mean that the element or layer can be directly on or directly connected to the other element(s) or layer(s), or that intervening elements or layers can be present. Further, where one element is referred to as being disposed “on,” “below,” “under,” etc. another element, it should be understood to mean that the elements can be so disposed to directly contact each other, or can be so disposed without directly contacting each other.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

The features of each of the various embodiments can be combined or combined with each another, in whole or in part, and various technical interlocking and driving can be possible, and each of the embodiments can be implemented independently of each other or in conjunction with each other.

In the present specification, a pixel circuit and a gate driver formed on a display panel can include a plurality of transistors. The transistors can be implemented with oxide thin film transistors (oxide TFTs) including an oxide semiconductor, low temperature polysilicon (LTPS) TFTs including low temperature polysilicon, and the like. In addition, each of the transistors can be implemented with a p-channel TFT or an n-channel TFT.

The transistor is a three-electrode element including a gate, a source, and a drain. The source is an electrode that supplies carriers to the transistor. Further, the carriers in the transistor start to flow from the source. In addition, the drain is an electrode through which the carriers are discharged from the transistor to the outside. Further, in the transistor, carriers flow from the source to the drain. In the case of an n-channel transistor, since carriers are electrons, a source voltage has a voltage lower than a drain voltage so that the electrons flow from the source to the drain. In this case, in the n-channel transistor, currents flow from the drain to the source. In the case of a p-channel transistor (PMOS), since carriers are holes, a source voltage is higher than a drain voltage so that the holes flow from the source to the drain. Further, in the p-channel transistor, since the holes flow from the source to the drain, currents flow from the source to the drain. It should be noted that the source and drain of the transistor are not fixed in position. For example, the source and drain are interchangeable depending on an applied voltage. Accordingly, the present embodiment is not limited by the source and drain of the transistor. In the following description, the source and the drain of the transistor will be referred to as a first electrode and a second electrode.

A gate signal swings between a gate-on voltage and a gate-off voltage. The gate-on voltage is set to be higher than a threshold voltage of the transistor, and the gate-off voltage is set to be lower than the threshold voltage of the transistor. The transistor is turned on in response to the gate-on voltage and turned off in response to the gate-off voltage. In the case of an n-channel transistor, the gate-on voltage can be a gate-high voltage VGH/VEH, and the gate-off voltage can be a gate-low voltage VGL/VEL. In the case of a p-channel transistor, the gate-on voltage can be a gate-low voltage VGL/VEL, and the gate-off voltage can be a gate-high voltage VGH/VEH.

Hereinafter, various embodiments of the present specification will be described in detail with reference to the accompanying drawings. Al components of each display device according to all embodiments of the present disclosure are operatively coupled and configured.

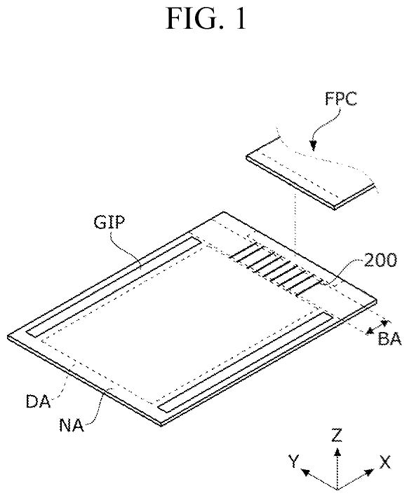

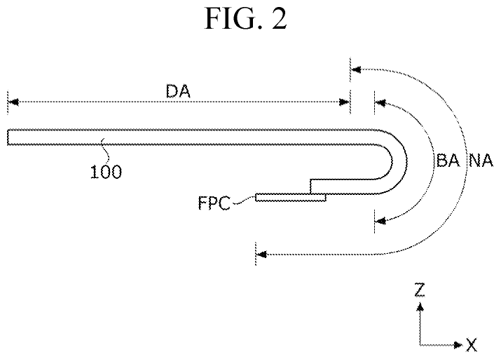

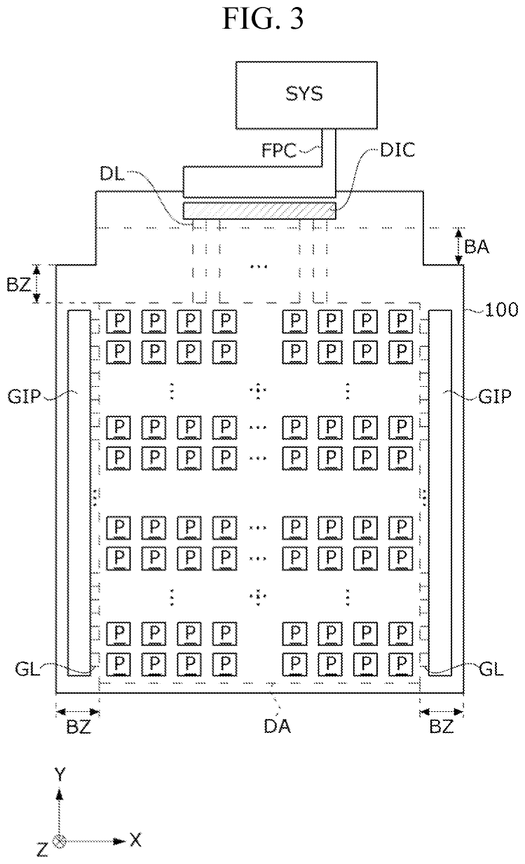

FIG. 1 is a perspective view illustrating a display device according to an example embodiment of the present specification, FIG. 2 is a cross-sectional view illustrating a bent state of the display device according to an example embodiment of the present specification, and FIG. 3 is a plan view illustrating a display device according to an example embodiment of the present specification.

An X-direction shown in FIGS. 1 and 2 can mean a width direction, a Y direction can mean a length direction, and a Z direction can mean a vertical direction, a stacking direction, or a thickness direction; however, other variations are possible. Here, the X, Y, and Z directions can be perpendicular to each other, but can also mean different directions that are not perpendicular to each other. In addition, planes extended in the X and Y directions can mean horizontal planes.

Referring to FIGS. 1 to 3, the display device according to the embodiments of the present specification can include a display panel 100 including a display area DA and a non-display area NA adjacent to the display area DA, a plurality of wirings 200 formed on the display panel 100, and an insulating layer formed to protrude from a bending area BA of the non-display area NA. For example, the non-display area NA can be extended from the display area DA. Here, the insulating layer can be disposed to be overlapped with a partial area of the wiring 200. In addition, the insulating layer can be formed in an island shape and can be provided as a metal layer.

In the display area DA of the display panel 100, data lines DL, gate lines GL crossing the data lines DL, and pixels P arranged in a matrix form defined by the data lines DL and the gate lines GL can be disposed. In addition, the display panel 100 can include a bezel area BZ that is a non-display area NA outside the display area DA.

Each of the pixels P includes sub-pixels having different colors for color implementation. The sub-pixels can include a red sub-pixel, a green sub-pixel, and a blue “sub-pixel. Each of the pixels P can further include a white sub-pixel. Hereinafter, a pixel can be interpreted as a sub-pixel unless otherwise defined, and any sub-pixel referred to herein can be any one of such sub-pixels or the like discussed herein. In addition, each of the sub-pixels can include a pixel circuit.

The pixel circuit can include a light emitting element, a driving element for supplying a current to the light emitting element, one or more switch elements for switching a current path between the driving element and the light emitting element, a capacitor for maintaining a gate-to-source voltage Vgs of the driving element, and the like.

The light emitting device can be implemented with an organic light emitting diode (OLED). The OLED includes an organic compound layer formed between an anode and a cathode. The organic compound layer can include a hole injection layer (HIL), a hole transport layer (HTL), a light emitting layer (EML), an electron transport layer (ETL) and an electron injection layer (EIL), but is not limited thereto. When a voltage is applied to an anode electrode and cathode electrode of the OLED, the holes passing through the hole transport layer (HTL) and the electrons passing through the electron transport layer (ETL) can be moved to the light emitting layer (EML) to generate excitons, and as a result, the visible light can be emitted from light emitting layer (EML).

The display panel driver writes pixel data of an input image into the pixels P. The display panel driver includes a data driver configured to supply data voltages of pixel data to the data lines DL and a gate driver GIP configured to sequentially supply gate pulses to the gate lines GL. The data driver is integrated into a drive integrated circuit (IC) DIC. The drive IC DIC can be bonded to the display panel 100.

The drive IC DIC is connected to the data lines DL through data output channels and supplies the voltage of the data signal to the data lines. The drive IC DIC includes a timing controller. The timing controller transmits pixel data of the input image received from a host system SYS to the data driver, and adjusts operation timings of the data driver and the gate driver GIP.

The data driver of the drive IC DIC converts the pixel data into a gamma compensation voltage through a digital-to-analog converter (DAC) and outputs a data voltage.

The gate driver GIP can include a shift register formed on a circuit layer of the display panel 100 together with a pixel array. The shift register of the gate driver GIP sequentially supplies gate signals to the gate lines GL under the control of the timing controller. The gate signal can include a scan pulse and a light emitting control pulse (hereinafter referred to as “pulse”). The shift register can include a scan driver configured to output scan pulses and an EM driver configured to output EM pulses.

The host system SYS can be implemented with an application processor (AP). The host system SYS transmits the pixel data of the input image to the drive IC DIC. The host system SYS can be connected to the drive IC DIC through a flexible printed circuit, for example, a flexible printed circuit FPC. Here, the flexible printed circuit can be formed on a flexible printed circuit board. As shown in FIG. 3, the drive IC DIC is disposed on the display panel 100 as an example, but is not necessarily limited thereto. For example, a drive IC DIC mounted on a flexible printed circuit board can be electrically connected to the display panel 100. The flexible circuit board on the display panel 100 can be bonded to the display panel 100 through a bonding process in a state where an anisotropic conductive film (ACF) is aligned in an area to be bonded.

In the present specification, the display panel 100 can be formed of an insulating material or a material having flexibility. For example, the display panel 100 of the present specification can be manufactured based on a thin, bendable glass or plastic substrate. The substrate can be a glass film with a thickness of 0.2 mm or less. In addition, a commercially available tempered glass film can be used as the glass film.

The display panel 100 can have a width in the X direction, a length in the Y direction, and a constant thickness in the Z direction. Since the display panel 100 can have a circuit layer and a light emitting element layer disposed on the substrate, the thickness thereof is thicker than that of the substrate. The width and length of the display panel 100 can be set to various design values depending on the application field of the display device. The display panel 100 can be manufactured in a rectangular plate shape, but is not limited thereto. For example, the display panel 100 can be manufactured as a differentiated panel including a curved portion. Here, if the thickness of the substrate of the display panel 100 is thin, it can be flexibly bent with a sufficiently predetermined curvature even with a small force.

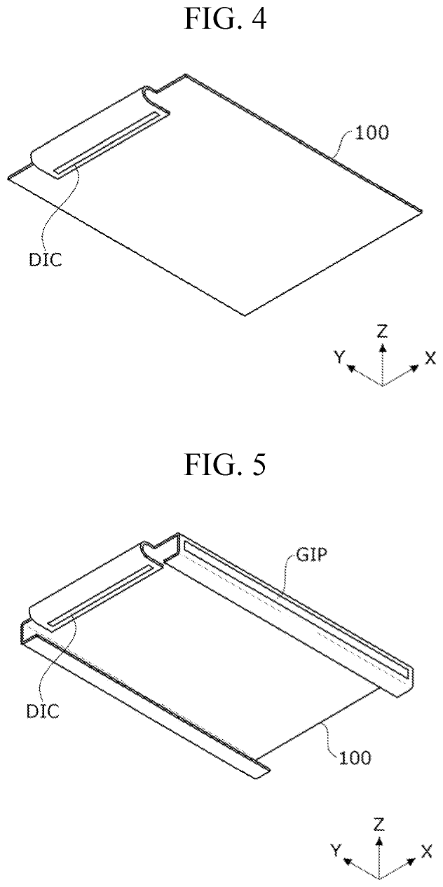

FIGS. 4 and 5 are views illustrating various examples in which a display panel of a display device according to an example embodiment of the present specification is bent.

As shown in FIG. 4, in the display panel 100, a partial area including a drive IC DIC can be bent backward. Accordingly, a bending area BA can be formed in the display panel 100, and an insulating layer can be disposed in the bending area BA.

As shown in FIG. 5, in the display panel 100, bezel areas BZ on both sides of the display panel 100 on which the gate driver GIP is mounted can be folded. Accordingly, a bending area BA can be formed in the bezel area BZ on both sides of the display panel 100 with respect to the X direction, and an insulating layer can be disposed in the bending area BA.

There can be a difference in electrical characteristics of a driving element between sub-pixels due to a process variation and an element characteristic variation caused in the manufacturing process of the display panel 100, and this difference can be more increased as the driving time of the pixels elapses. In order to compensate for the electrical characteristic variation of the driving element between pixels, an internal compensation technique and/or external compensation technique can be applied to the organic light-emitting display device.

The internal compensation technique uses an internal compensation circuit implemented in each of the pixel circuits to sense a threshold voltage of the driving element for each sub-pixel and compensate for a gate-source voltage Vgs of the driving element by as much as the threshold voltage.

The external compensation technique uses an external compensation circuit to sense a current or voltage of the driving element, which changes according to the electrical characteristics of the driving elements, in real-time. The external compensation technique compensates for an electrical characteristic variation (or change) of the driving element in each of the pixels in real-time by modulating pixel data (digital data) of an input image by as much as the electrical characteristic variation (or change) of the driving element sensed for each pixel.

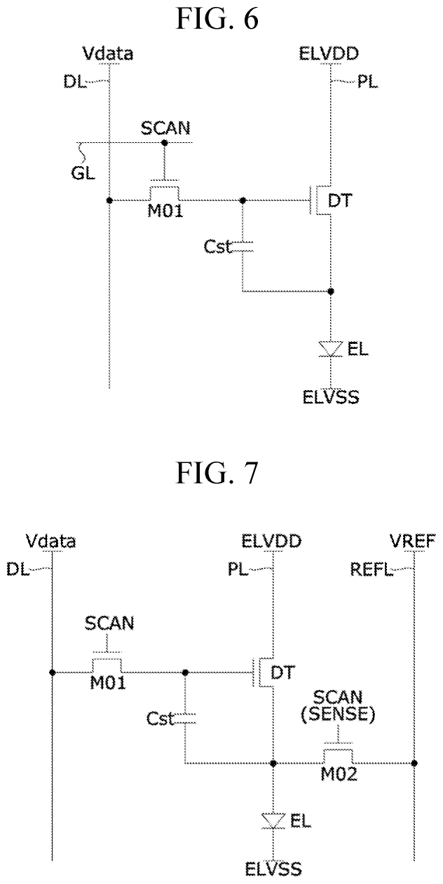

FIGS. 6 to 8 are circuit diagrams illustrating various pixel circuits applicable to a display area of a display device according to an example embodiment of the present specification. It should be noted that the pixel circuit in this specification is not limited to FIGS. 6 to 8.

Referring to FIG. 6, the pixel circuit includes a light emitting element EL, a driving element DT configured to supply a current to the light emitting element EL, a switch element M01 configured to connect a data line DL in response to a scan pulse SCAN, and a capacitor Cst connected to a gate electrode of the driving element DT. In this pixel circuit, the driving element DT and the switch element M01 can be implemented with n-channel transistors.

The switch element M01 is turned on depending on a gate-on voltage of the scan pulse SCAN to connect the data line DL to the gate electrode of the driving element DT.

The driving element DT includes a first electrode connected to a VDD line PL to which a pixel driving voltage ELVDD is applied, a gate electrode connected to the switch element M01 and the capacitor Cst, and a second electrode connected to the light emitting element EL. In addition, the driving element DT drives the light emitting element EL by supplying a current to the light emitting element EL depending on a gate-source voltage Vgs. Here, the light emitting element EL is turned on and emits light when a forward voltage between an anode electrode and a cathode electrode is greater than or equal to a threshold voltage.

The capacitor Cst is connected between the gate electrode and the second electrode of the driving element DT to store the gate-source voltage Vgs of the driving element DT.

Referring to FIG. 7, the pixel circuit can further include a second switch element M02 connected between a reference line REFL and the second electrode of the driving element DT. In this pixel circuit, the driving element DT and the switch elements M01 and M02 can be implemented with n-channel transistors.

The second switch element M02 is turned on depending on the gate-on voltage of the scan pulse SCAN or a sensing pulse SENSE to connect the reference line REFL to which a reference voltage Vref is applied to the second electrode of the driving element DT.

In the sensing mode, a current flowing through a channel of the driving element DT or a voltage between the driving element DT and the light emitting element EL can be sensed through the reference line REFL. The current flowing through the reference line REFL is converted into a voltage through an integrator and converted into digital data through an analog-to-digital converter (hereinafter referred to as “ADC”). This digital data is sensing data including a threshold voltage or mobility information of the driving element DT. The sensing data can be transmitted to a compensator of the drive IC DIC. In addition, the compensator can receive sensing data from the ADC and compensate for a threshold voltage deviation or variation of the driving element DT by adding or multiplying a compensation value selected based on the sensing data to pixel data.

The pixel circuit shown in FIGS. 6 and 7 can further include an EM switch element configured to switch a current path of the light emitting element EL in response to an EM pulse. The EM switch element can be connected between the pixel driving voltage ELVDD and the driving element DT or between the driving element DT and the light emitting element EL.

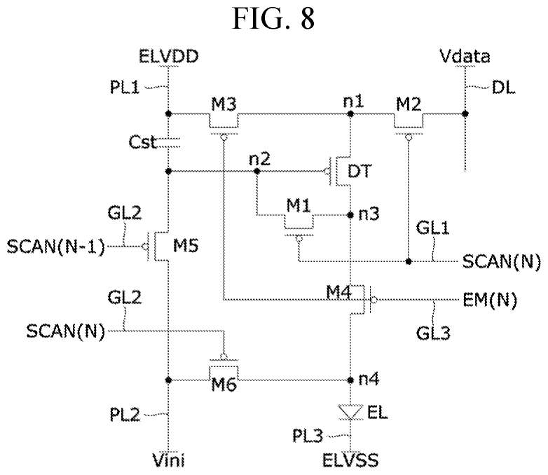

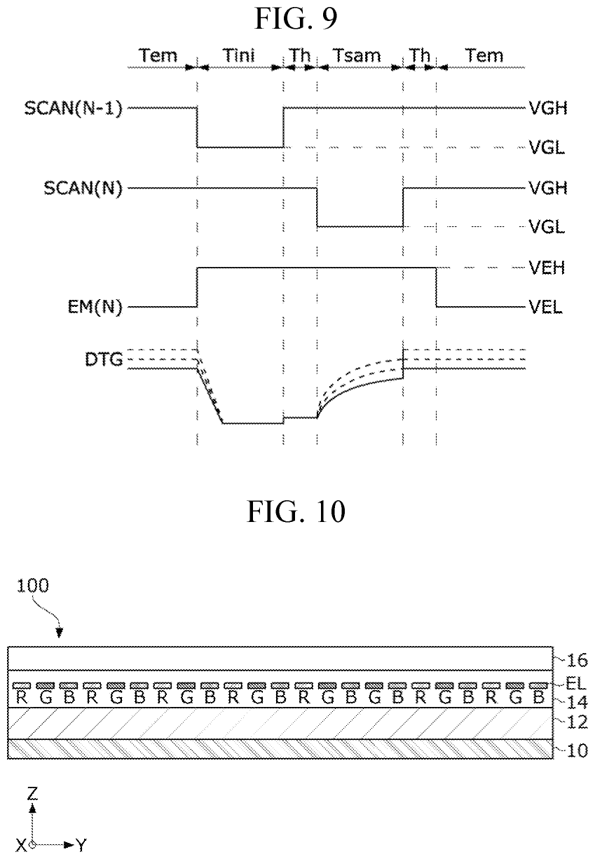

FIG. 8 is a circuit diagram showing one example of a pixel circuit to which an internal compensation circuit is applied, and FIG. 9 is a waveform diagram illustrating a driving method of the pixel circuit shown in FIG. 8.

Referring to FIGS. 8 and 9, the pixel circuit includes a light emitting element EL, a driving element DT configured to supply a current to the light emitting element EL, and a switch circuit configured to switch voltages applied to the light emitting element EL and the driving element DT.

The switch circuit is connected to power lines PL1, PL2, and PL3 to which a pixel driving voltage ELVDD, a low potential power supply voltage ELVSS, and an initialization voltage Vini are applied, a data line DL, and gate lines GL1, GL2 and GL3. The switch circuit switches voltages applied to the light emitting element EL and the driving element DT in response to the scan pulses SCAN(N−1) and SCAN(N)) and the EM pulses EM(N).

The switch circuit samples a threshold voltage Vth of the driving element DT using a plurality of switch elements M1 to M6, stores it in the capacitor Cst, and compensates for a gate voltage of the driving element DT as much as the threshold voltage Vth of the driving element DT. Here, the driving element DT and each of the switch elements M1 to M6 can be implemented with a p-channel transistor.

A driving period of the pixel circuit can be divided into an initialization period Tini, a sampling period Tsam, and a light emission period Tem, as shown in FIG. 9.

An Nth scan pulse SCAN(N) is generated as a gate-on voltage VGL in the sampling period Tsam and applied to a first gate line GL1. An N−1th scan pulse SCAN(N−1) is generated prior to the Nth scan pulse SCAN(N) and applied to a second gate line GL2. The N−1th scan pulse SCAN(N−1) defines the initialization period Tini. The EM pulse EM(N) is generated as a gate-off voltage VEH during the initialization period Tin and the sampling period Tsam, and is applied to a third gate line GL3.

During the initialization period Tini, the N−1th scan pulse SCAN(N−1) is generated as the gate-on voltage VGL and applied to the second gate line GL2. During the initialization period Tini, the voltages of the first and third gate lines GL1 and GL3 are gate-off voltages VGH and VEH.

The Nth scan pulse SCAN(N) is generated as a pulse of the gate-on voltage VGL during the sampling period Tsam and applied to the first gate line GL1. During the sampling period Tsam, the voltages of the second and third gate lines GL2 and GL3 are gate-off voltages VGH.

The EM pulse EM(N) is generated as a gate-on voltage VEL during at least a portion of the light emitting period Tem and applied to the third gate line GL3. During the light emitting period Tem, voltages of the first and second gate lines GL1 and GL2 are gate-off voltages VGH.

The anode electrode of the light emitting element EL is connected to a fourth node n4 between the fourth and sixth switch elements M4 and M6. The fourth node n4 is connected to the anode electrode of the light emitting element EL, a second electrode of the fourth switch element M4, and a second electrode of the sixth switch element M6. The cathode electrode of the light emitting element EL is connected to a VSS line PL3 to which the low potential power supply voltage ELVSS is applied. The light emitting element EL emits light with a current flowing depending on the gate-source voltage Vgs of the driving element DT. The current path of the light emitting element EL is switched by the second and fourth switch elements M2 and M4.

The capacitor Cst is connected between a VDD line PL1 and a second node n2. Here, the capacitor Cst includes a first electrode connected to the VDD line PL1 and a second electrode connected to the second node n2. In addition, the data voltage Vdata compensated for as much as the threshold voltage Vth of the driving element DT is charged in the capacitor Cst. Since the data voltage Vdata in each of the sub-pixels is compensated for as much as the threshold voltage Vth of the driving element DT, deviation (or variation) in characteristics of the driving element DT in the sub-pixels is compensated for.

The first switch element M1 is turned on depending on the gate-on voltage VGL of the Nth scan pulse SCAN(N) to connect the second node n2 and a third node n3. Further, the second node n2 is connected to the gate electrode of the driving element DT, the second electrode of the capacitor Cst, and a first electrode of the first switch element M1. In addition, the third node n3 is connected to the second electrode of the driving element DT, the second electrode of the first switch element M1, and a first electrode of the fourth switch element M4. In addition, a gate electrode of the first switch element M1 is connected to the first gate line GL1 to receive the Nth scan pulse SCAN(N). Further, the first electrode of the first switch element M1 is connected to the second node n2, and the second electrode of the first switch element M1 is connected to the third node n3.

The first switch element M1 is turned off because it is turned on during one very short horizontal period (1H) in which the Nth scan pulse SCAN(N) is generated as the gate-on voltage VGL in one frame period. In this state, a leakage current can be generated. In order to suppress the leakage current of the first switch element M1, the first switch element M1 can be implemented with a transistor having a dual gate structure in which two transistors are connected in series.

The second switch element M2 is turned on depending on the gate-on voltage VGL of the Nth scan pulse SCAN(N) to supply the data voltage Vdata to the first node n1. Further, a gate electrode of the second switch element M2 is connected to the first gate line GL1 to receive the Nth scan pulse SCAN(N). In addition, the first electrode of the second switch element M2 is connected to the first node n1. Further, the second electrode of the second switch element M2 is connected to the data line DL to which the data voltage Vdata is applied. In addition, the first node n1 is connected to the first electrode of the second switch element M2, the second electrode of the third switch element M3, and the first electrode of the driving element DT.

The third switch element M3 is turned on depending on the gate-on voltage VGL of the EM pulse EM(N) to connect the VDD line PL1 to the first node n1. Further, the gate electrode of the third switch element M3 is connected to the third gate line GL3 to receive the EM pulse EM(N). In addition, the first electrode of the third switch element M3 is connected to the VDD line PL1. Further, the second electrode of the third switch element M3 is connected to the first node n1.

The fourth switch element M4 is turned on depending on the gate-on voltage VEL of the EM pulse EM(N) to connect the third node n3 to the fourth node n4. Further, the gate electrode of the fourth switch element M4 is connected to the third gate line GL3 to receive the EM pulse EM(N). In addition, the first electrode of the fourth switch element M4 is connected to the third node n3, and the second electrode is connected to the fourth node n4.

The fifth switch element M5 is turned on depending on the gate-on voltage VGL of the N−1th scan pulse SCAN(N−1) to connect the second node n2 to the Vini line PL2. Further, a gate electrode of the fifth switch element M5 is connected to the second gate line GL2 to receive the N−1th scan pulse SCAN(N−1). Further, the first electrode of the fifth switch element M5 is connected to the second node n2, and the second electrode is connected to the Vini line PL2 to which the initialization voltage Vini is applied. In order to suppress a leakage current of the fifth switch element M5, the fifth switch element M5 can be implemented with a transistor having a dual gate structure in which two transistors are connected in series.

The sixth switch element M6 is turned on depending on the gate-on voltage VGL of the Nth scan pulse SCAN(N) to connect the Vini line PL2 to the fourth node n4. Further, the gate electrode of the sixth switch element M6 is connected to the first gate line GL1 to receive the Nth scan pulse SCAN(N). In addition, the first electrode of the sixth switch element M6 is connected to the Vini line PL2, and the second electrode is connected to the fourth node n4. In another embodiment, the gate electrodes of the fifth and sixth switch elements M5 and M6 can be connected in common to the second gate line GL2 to which the N−1th scan pulse SCAN(N−1) is applied. In this case, the fifth and sixth switch elements M5 and M6 can be turned on simultaneously in response to the N−1th scan pulse SCAN(N−1) in the initialization period Tini.

The driving element DT adjusts a current flowing through the light emitting element EL depending on the gate-source voltage Vgs to drive the light emitting element EL. Here, the driving element DT includes a gate connected to the second node n2, a first electrode connected to the first node n1, and a second electrode connected to the third node n3.

During the initialization period Tini, the N−1th scan pulse SCAN(N−1) is generated as the gate-on voltage VGL. The Nth scan pulse SCAN(N) and the EM pulse EM(N) maintain gate-off voltages VGH and VEH during the initialization period Tini. Therefore, during the initialization period Tini, the fifth switch element M5 is turned on and the second node n2 is initialized to the initialization voltage Vini. When the fifth and sixth switch elements M5 and M6 are turned on during the initialization period Tini, the second and fourth nodes n2 and n4 are initialized to the initialization voltage Vini.

A hold period Th can be set between the initialization period Tini and the sampling period Tsam and between the sampling period Tsam and the light emission period Tem. In the hold period, the scan pulses SCAN(N−1) and SCAN(N) and the EM pulse EM(N) are the gate-off voltage VGH, and the main nodes n1 to n4 of the pixel circuit are floated.

During the sampling period Tsam, the Nth scan pulse SCAN(N) is generated as the gate-on voltage VGL. The pulse of the Nth scan pulse SCAN(N) is synchronized with the data voltage Vdata of pixel data to be written in the sub-pixels of the Nth pixel line. The N−1th scan pulse SCAN(N−1) and the EM pulse EM(N) are the gate-off voltages VGH and VEH during the sampling period Tsam. Accordingly, the first and second switch elements M1 and M2 are turned on during the sampling period Tsam. In this case, the sixth switch element M6 is also turned on and supplies the initialization voltage Vini to the fourth node n4 to prevent the light emitting element EL from emitting light.

During the sampling period Tsam, the gate voltage DTG of the driving element DT is increased by the current flowing through the first and second switch elements M1 and M2. In the sampling period Tsam, the threshold voltage Vth of the driving element DT is sampled by the capacitor Cst.

During the light emitting period Tem, the EM pulse EM(N) can be generated as the gate-on voltage VGL. During the light emission period Tem, the voltage of the EM pulse EM(N) can be reversed at a predetermined duty ratio. Accordingly, the EM pulse EM(N) can be generated as the gate-on voltage VGL during at least a portion of the light emission period Tem.

When the EM pulse EM(N) is the gate-on voltage VEL, a current flows between the pixel driving voltage ELVDD and the light emitting element EL, so that the light emitting element EL can emit light. During the light emission period Tem, the N−1th and Nth scan pulses SCAN(N−1) and SCAN(N)) are gate-off voltages VGH. During the light emission period Tem, the third and fourth switch elements M3 and M4 are turned on depending on the gate-on voltage VEL of the EM pulse EM. When the EM pulse EM(N) is the gate-on voltage VEL, the third and fourth switch elements M3 and M4 are turned on and the current flows through the light emitting element EL. During the light emitting period Tem, the current flowing through the light emitting element EL is K(ELVDD−Vdata)². K is a constant value determined by charge mobility, parasitic capacitance, and channel capacitance of the driving element DT.

It is to be noted that FIGS. 6 to 8 show some examples of the pixel circuits applicable to a display area of a display device, such as 2T (transistor) 1C (capacitor), 3T1C or 7T1C structure, but the present disclosure is not limited thereto. The pixel structure can further include one or more transistors, or can further include one or more capacitors, if needed. Alternatively, each of the subpixels in the display area can have the same pixel structure, and some of the subpixels can have the different pixel structures.

FIGS. 10 to 12 are cross-sectional views schematically illustrating cross-sectional structures of a display area of a display device according to an example embodiment of the present specification.

Referring to FIG. 10, the display panel 100 can include a circuit layer 12, a light emitting element layer 14, and an encapsulation layer 16 stacked on a substrate 10.

The substrate 10 can be formed of an insulating material or a material having flexibility. For example, the substrate 10 can be made of glass, metal, plastic, or the like, but is not limited thereto. However, when the substrate 10 is made of plate-shaped alkali-free glass or non-alkali glass, it has greater resistance to impact and is not deformed than a plastic substrate.

The circuit layer 12 can include a pixel circuit connected to wirings such as data lines, gate lines, and power lines, and a gate driver GIP connected to the gate lines, or the like. Further, the wirings and circuit elements of the circuit layer 12 can include a plurality of insulating layers, two or more metal layers separated with the insulating layer interposed therebetween, and an active layer including a semiconductor material.

The light emitting element layer 14 can include a light emitting element EL driven by a pixel circuit. Further, the light emitting element EL can include a red light emitting element, a green light emitting element, and a blue light emitting element. In another embodiment, the light emitting element layer 14 can include a white light emitting element and a color filter. The light emitting elements EL of the light emitting element layer 14 can be covered by a protective layer including an organic film and a protective film.

The encapsulation layer 16 covers the light emitting element layer 14 so as to seal the circuit layer 12 and the light emitting element layer 14. Here, the encapsulation layer 16 can have a multi-insulation layer structure in which organic layers and inorganic films are alternately stacked. In this case, the inorganic film blocks penetration of moisture or oxygen. The organic layer flattens the surface of the inorganic film. When the organic layer and the inorganic film are stacked in multiple layers, the movement path of moisture or oxygen is longer than that of a single layer, so that penetration of moisture/oxygen affecting the light emitting element layer 14 can be effectively blocked.

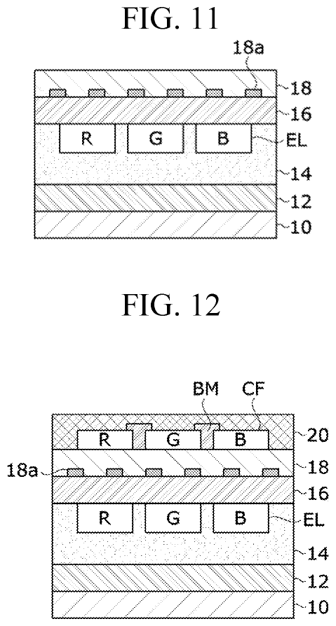

Referring to FIG. 11, the display panel 100 can further include a touch sensor layer 18 formed on the encapsulation layer 16. The touch sensor layer 18 can be implemented with capacitive touch sensors that sense a touch input based on a change in capacitance before and after the touch input. The touch sensor layer 18 includes conductor wiring patterns 18a forming capacitance of the touch sensors. The capacitance of the touch sensor can be formed between the conductive patterns 18a.

The touch sensor layer 18 can include an organic layer covering the conductor wiring patterns 18a of the touch sensors. An extended portion of the organic film can cover the remaining inorganic film or the substrate 10 in the bezel area BZ, for example, an edge area of the display panel 100.

On the touch sensor layer 18, a polarizing plate, which is omitted in the drawings, can be bonded. The polarizing plate can improve visibility and contrast ratio by converting polarization of external light reflected by the metal patterns of the circuit layer 12. Here, the polarizing plate can be implemented with a polarizing plate in which a linear polarizing plate and a phase retardation film are bonded together or a circular polarizing plate. Further, a cover glass, which is omitted in the drawings, can be bonded on the polarizing plate.

Referring to FIG. 12, the display panel 100 can further include a touch sensor layer 18 formed on the encapsulation layer 16 and a color filter layer 20 formed on the touch sensor layer 18.

The color filter layer 20 can include red, green, and blue color filters CF. In addition, the color filter layer 20 can further include a black matrix pattern BM. The color filter layer 20 can absorb some wavelengths of light reflected from the circuit layer 12 to serve as a polarizing plate and increase color purity. In this embodiment, the light transmittance of the display panel 100 can be improved and the thickness and flexibility of the display panel 100 can be improved by applying the color filter layer 20 having higher light transmittance than that of the polarizing plate to the display panel. On the color filter layer 20, a cover glass, which is omitted in the drawings, can be bonded.

The color filter layer 20 can include an organic film covering the color filter and the black matrix pattern. An extended portion of the organic film can cover the remaining inorganic film or the substrate 10 in the bezel area BZ, for example, an edge area of the display panel 100.

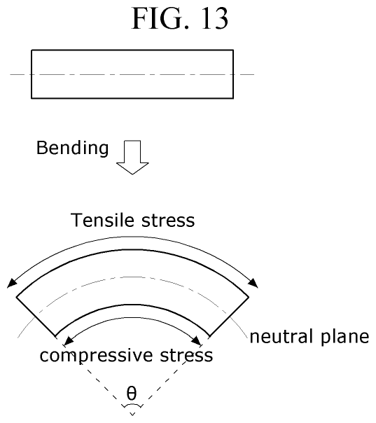

FIG. 13 is a diagram illustrating a neutral plane depending on a bending in a bending area of a display device according to an example embodiment of the present specification.

Referring to FIG. 13, when a position of the neutral plane formed in the bending area BA is positioned close to the center of the wiring(s) 200, the stresses acting on the wirings 200 such as the gate lines GL and the data lines DL can be reduced when the display panel is bent.

Here, the neutral plane can be defined as a plane having a stress state of 0 when the display panel is bent, and the magnitude of tensile stress or compressive stress is determined in proportion to a distance from the neutral plane. Further, the center of each wiring 200 can be positioned at the center between a surface on which the tensile stress is applied and a surface on which the compressive stress is applied with respect to the Z direction. Here, the surface on which the compressive stress acts can be defined as a surface disposed close to the center of curvature, and the surface on which the tensile stress acts can be defined as a surface opposite to the surface on which the compressive stress acts.

Additionally, crack is more likely to occur in the wiring 200 disposed in an area where the tensile stress acts than in the wiring 200 disposed in an area where the compressive stress acts. For example, when the display panel is bent, an area of the wiring 200 subjected to the tensile stress is more vulnerable to crack generation than an area subjected to the compressive stress.

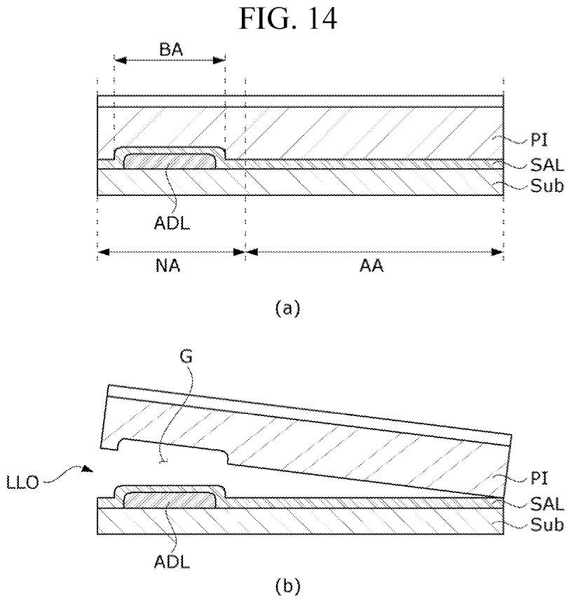

As described above, an additional layer ADL (FIG. 14) is formed at a position where the compressive stress and the tensile stress act in the display panel 100, for example, in the bending area BA, thereby minimizing or reducing the stress applied to the wiring 200. Accordingly, defects due to cracks in the wiring 200 can be improved.

FIG. 14 is a diagram illustrating a manufacturing process of a substrate formed including a groove according to an example embodiment of the present specification.

Referring to FIG. 14, the display device according to an example embodiment of the present specification can first form a substrate PI having a flexible property on a support substrate Sub.

The support substrate Sub can be formed of various materials such as a glass material having sufficient rigidity and a metal material. Since the substrate PI of the display device itself has a flexible property, the support substrate Sub serves to support the substrate PI while various layers to be described below are formed on the substrate PI.

Prior to forming the substrate PI on the support substrate Sub, the additional layer ADL can be first formed. The additional layer ADL is formed on the support substrate Sub to be positioned in the non-display area NA or the bending area BA in the display panel 100.

After the additional layer ADL is formed, a sacrificial layer SAL is formed on the entire surface of the additional layer ADL and the support substrate Sub. The sacrificial layer SAL can include an alkali metal formed by a method such as sputtering, PVD, or CVD. For example, it can be formed of a metal layer containing lithium (Li), sodium (Na), potassium (K), and the like. Accordingly, the sacrificial layer SAL can be Li₂O₂, Na₂O₂, K₂O₂, etc., but the present specification is not necessarily limited to the above materials. The sacrificial layer SAL can be formed to have a thickness of 10 nm to 100 nm, and preferably can be formed to have a thickness of 20 nm to 50 nm.

After forming the sacrificial layer SAL, the step of forming the substrate PI on the sacrificial layer SAL can be performed. The substrate PI has a flexible property, and can be formed of various materials, such as a metal material, or plastic materials such as polyethylene terephthalate (PET), polyethylene naphthalate (PEN), polyester (PES), polyetheretherketone (PEEK), polycarbonate (PC), and polyimide (PI). In some cases, a thin metal foil such as steel use stainless (SUS) can be used.

After sequentially forming the additional layer ADL, the sacrificial layer SAL, and the substrate PI on the support substrate Sub, a lift-off (LLO) process is performed by irradiating the sacrificial layer SAL with a laser and thus the step of separating the substrate PI from the support substrate Sub can be performed.

The substrate PI formed through the above process has a groove G in the non-display area NA or the bending area BA, and the neutral plane can be positioned close to the center of the wiring due to the groove G overlapped with the wiring formed later on the bending area BA.

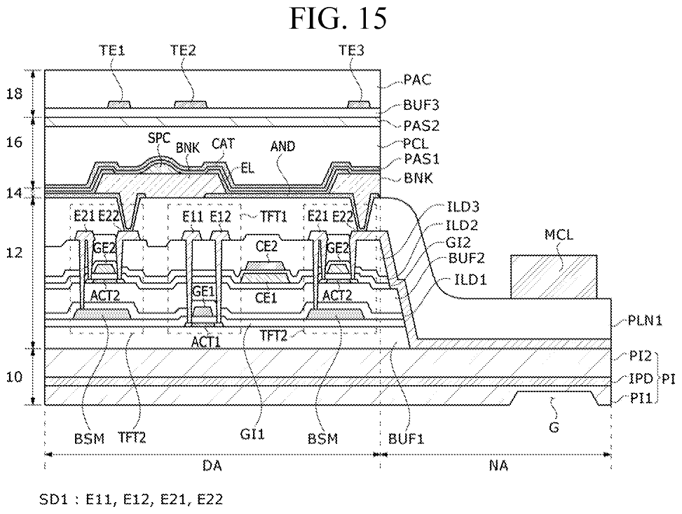

FIG. 15 is a diagram illustrating a cross-sectional structure of a display area in a display device according to an example embodiment of the present specification.

Referring to FIG. 15, a TFT represents a driving element DT of a pixel circuit. In detail, “TFT1” is a first TFT that is one of LTPS TFTs disposed on the display area DA, and “TFT2” is a second TFT that is one of oxide TFTs disposed on the display area DA. Here, it should be noted that the cross-sectional structure of the display area DA is not limited to that of FIG. 15. A plurality of sub-pixel circuits and wirings connected to the pixel circuits are disposed in the display area DA of the display panel 100. Here, the pixel circuits of the display area DA include a red sub-pixel pixel circuit configured to drive a red light emitting element, a green sub-pixel pixel circuit configured to drive a green light emitting element, and a blue sub-pixel pixel circuit configured to drive a blue light emitting element. Further, the display area DA is divided into a plurality of circuit areas along the X-axis direction of the display panel 100.

The bending area BA can be formed in the non-display area NA extended outside the display area DA. The bending area BA is an area where the substrate PI of the display panel 100 is bent, and a portion of the display panel 100 bent through the bending area BA can be bent in a shape having an angle in the display area DA. Accordingly, a portion of the non-display area NA can be disposed in a shape facing the rear surface of the display area DA. In this case, the substrate PI of the bending area BA can include a groove formed to adjust the neutral plane.

In addition, the substrate PI can include first and second substrates PI1 and PI2. Further, an inorganic film IPD can be formed between the first substrate PI1 and the second substrate PI2. In this case, the inorganic film IPD blocks moisture permeation. Here, since the substrate PI can be formed of polyimide, it can be referred to as a PI substrate, and the first and second substrates PI1 and PI2 can be referred to as first and second PI substrates.

The first buffer layer BUF1 can be formed on the second substrate PI2. The first buffer layer BUF1 can be formed of a multi-layered insulating film in which two or more silicon dioxide films SiO₂ and silicon nitride films SiNx are stacked. A first semiconductor layer is formed on the first buffer layer BUF1. The first semiconductor layer can include a polysilicon semiconductor layer patterned in a photolithography process. The first semiconductor layer can include a polysilicon active pattern ACT1 forming a semiconductor channel in the first TFT TFT1.

A first gate insulating layer GI1 is deposited on the first buffer layer BUF1 to cover the active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer includes a single metal layer patterned in a photolithography process or metal patterns in which two or more metal layers are stacked. The first metal layer can include the gate electrode GE1 of the first TFT TFT1 and a light shield pattern BSM under the second TFT TFT2.

A first interlayer insulating layer ILD1 is formed on the first gate insulating layer GI1 to cover the patterns of the first metal layer. The first interlayer insulating layer ILD1 includes an inorganic insulating material. A second buffer layer BUF2 is formed on the first interlayer insulating layer ILD1. The second buffer layer BUF2 includes a single layer or a multi-layer inorganic insulating material.

A second semiconductor layer includes an oxide semiconductor pattern ACT2 forming a semiconductor channel in the second TFT TFT2. The second gate insulating layer GI2 is deposited on the second buffer layer BUF2 to cover the active pattern ACT2 of the second semiconductor layer. The second gate insulating layer GI2 includes a single or multi-layered inorganic insulating material. A second metal layer is formed on the second gate insulating layer GI2. The second metal layer is insulated from the second semiconductor layer by the second gate insulating layer GI2.

The second metal layer includes a single metal layer patterned in a photolithography process or metal patterns in which two or more metal layers are stacked. The second metal layer includes the gate electrode GE2 of the second TFT TFT2 and a lower capacitor electrode CE1.

A second interlayer insulating layer ILD2 is formed on the second gate insulating layer GI2 to cover the patterns of the second metal layer. The second interlayer insulating layer ILD2 includes a single layer or a multi-layered inorganic insulating material. A third metal layer is formed on the second interlayer insulating layer ILD2. The third metal layer is insulated from the second metal layer by the second interlayer insulating layer ILD2.

The third metal layer includes a single metal layer patterned in a photolithography process or metal patterns in which two or more metal layers are stacked. The third metal layer includes an upper capacitor electrode CE2. The capacitor Cst of the pixel circuit includes an upper capacitor electrode CE2, a lower capacitor electrode CE1, and a dielectric layer therebetween, for example, a second interlayer insulating layer ILD2.

A third interlayer insulating layer ILD3 covering the patterns of the third metal layer is formed on the second interlayer insulating layer ILD2. The third interlayer insulating layer ILD3 includes a single layer or a multi-layer inorganic insulating material. A fourth metal layer is formed on the third interlayer insulating layer ILD3. The fourth metal layer is insulated from the second semiconductor layer by the second gate insulating layer GI2.

The fourth metal layer SD1 includes a single metal layer patterned in a photolithography process or metal patterns in which two or more metal layers are stacked. The fourth metal layer includes first and second electrodes E11 and E12 of the first TFT TFT1 and first and second electrodes E21 and E22 of the second TFT TFT2. The first and second electrodes E11 and E12 of the first TFT TFT1 are connected to a first active pattern ACT1 through a first contact hole passing through the insulating layers GI1, ILD1, BUF2, GI2, ILD2 and ILD3. The first and second electrodes E21 and E22 of the second TFT TFT2 are connected to a second active pattern ACT2 through a second contact hole passing through the insulating layers GI2, ILD2 and ILD3. The first electrode E21 of the second TFT TFT2 can be connected to the light shield pattern BSM through a third contact hole passing through the insulating layers ILD1, BUF2, GI2, ILD2, and ILD3. Here, an electric field with high intensity can be generated in the metal patterns E11 to E22 of the fourth metal layer due to voltages swinging between a gate-on voltage and a gate-off voltage having a large voltage difference.

The wiring formed on the substrate PI in the bending area BA can be formed of the same material as the fourth metal layer SD1 formed as the first and second electrodes in the first TFT or second TFT of the display area DA, and can be electrically connected to at least some of them.

The first planarization layer PLN1 covers the patterns E11 to E22 of the fourth metal layer. The first planarization layer PLN1 thickly covers the display area DA of the circuit layer 12 with an organic insulating material. When the first planarization layer PLN is applied on the circuit layer 12, the organic insulating material flows to an edge of the display panel 100 and covers the side surface of the circuit layer 12 in the bezel area BZ.

The first planarization layer PLN1 is extended from the display area DA to the non-display area NA and is formed to cover a plurality of wirings in the bending area BA.

In the bending area BA, a micro cover layer MCL can be formed on the first planarization layer PLN1, and can be formed of an inorganic insulating material or organic insulating material, but the present disclosure is not limited thereto. The micro cover layer MCL can be disposed to be overlapped with the plurality of wirings 200 and can be formed in an island shape or stripe shape. The micro cover layer MCL can allow the plurality of wirings 200 on the bending area BA to withstand stresses due to bending of the substrate PI by adjusting a position of the neutral plane. For example, at least based on the micro cover layer MCL, the position of the neutral plane can be adjusted to be closer to, or within the plurality of wirings 200, such that the stresses due to bending of the substrate PI can be minimized, prevented or reduced. The micro cover layer MCL can also be referred to as a neutral plane adjustment layer or stress reduction layer, but the present disclosure is not limited thereto. In addition, the micro cover layer MCL can prevent the wirings 200 from being directly exposed to an external force.

In addition, the micro cover layer MCL can be formed to be overlapped with the groove G formed on the substrate PI so that the neutral plane is positioned closer to the wiring 200 in the bending area BA. It is to be noted that both the micro cover layer MCL and the groove G are utilized to reduce the stress applied to the wirings 200 during the bending, and either micro cover layer MCL or the groove G can be omitted when the remaining one can place the neutral plane at or close to the center of the wirings 200.

The sixth metal layer includes a single metal layer patterned in a photolithography process or metal patterns in which two or more metal layers are stacked. The pattern of the sixth metal layer includes an anode electrode AND of the light emitting element EL. The anode electrode AND is in contact with the second electrode E22 of the second TFT TFT2 of the pixel circuits through the fifth contact hole penetrating the first planarization layer PLN1.

Although the anode electrode AND is shown in contact with the second electrode E22 of the second TFT TFT2 in FIG. 15, it is not limited thereto. For example, according to a design, the anode electrode AND can be in contact with the second electrode E12 of the first TFT TFT1, or can be in contact with both the second electrode E12 of the first TFT TFT1 and the second electrode E22 of the second TFT TFT2.

In the light emitting element layer 14, a bank BNK is formed on the first planarization layer PLN1 to cover an edge of the anode electrode AND. In this case, the bank BNK is formed in a pattern defining a light emitting area (or an opening area) through which light passes from each of pixels to the outside. Accordingly, the bank BNK can be referred to as a pixel defining film. The bank BNK can be patterned in a photolithography process by including an organic insulating material having photosensitivity. Further, a spacer SPC having a predetermined height can be formed on the bank BNK. In this case, the bank BNK and the spacer SPC can be integrated with the same organic insulating material. In addition, the spacer SPC secures a gap between a fine metal mask (FMM) and the anode electrode AND so that the FMM) may not be contact with the anode electrode AND in the deposition process of the light emitting element EL formed of an organic compound.

A seventh metal layer used as a cathode electrode CAT of the light emitting element EL is formed on the light emitting element EL implemented with the bank BNK and an organic compound layer. The seventh metal layer is connected between sub-pixels in the display area DA.

The encapsulation layer 16 includes multiple insulating layers covering the cathode electrode CAT of the light emitting element EL. The multiple insulating layers include a first inorganic insulating layer PAS1 covering the cathode electrode CAT, a thick organic insulating layer PCL covering the first inorganic insulating layer PAS1, and a second inorganic insulating layer PAS2 covering the organic insulating layer PCL.

The touch sensor layer 18 includes a third buffer layer BUF3 covering the second inorganic insulating layer PAS2, sensor electrode wirings TE1 to TE3 formed on the third buffer layer BUF3, and an organic insulating layer PAC covering the sensor electrode wirings TE1 to TE3.

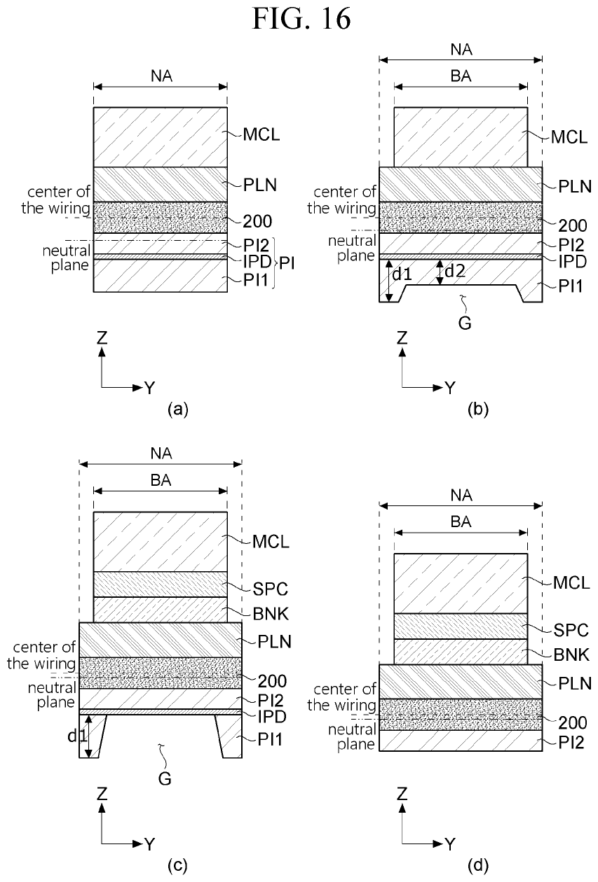

FIG. 16 is a schematic diagram illustrating a movement of a neutral plane in a bending area of a display device according to an example embodiment of the present specification.

More specifically, (a) of FIG. 16 is a diagram illustrating a neutral plane disposed in a bending area of a display device according to a comparative example, (b) of FIG. 16 is a diagram illustrating a neutral plane disposed in a bending area of a display device according to an example embodiment of the present specification, (c) of FIG. 16 is a diagram illustrating a movement of a neutral plane in a bending area of a display device according to another example embodiment of the present specification, and (d) of FIG. 16 is a diagram illustrating a movement of a neutral plane in a bending area of a display device according to another example embodiment of the present specification.

Referring to (a) of FIG. 16, a non-display area NA of the display device according to the comparative example can include a substrate PI, a wiring 200 disposed on the substrate PI, and a planarization layer PLN disposed on the wiring 200. In addition, the bending area BA of the display device according to the comparative example can further include a micro cover layer MCL disposed on the planarization layer PLN.

Here, the substrate PI can include a first substrate PI1, a second substrate PI2, and an inorganic film IPD disposed between the first substrate PI1 and the second substrate PI2. In addition, the inorganic film IPD blocks moisture permeation. Further, the micro cover layer MCL is provided as an insulating layer, and allows a position of the neutral plane to be adjusted.

As shown in (a) of FIG. 16, the neutral plane of the comparative example disposed to be spaced apart from the center of the wiring 200 in the Z direction is positioned on the substrate PI.

Referring to (b) of FIG. 16, in the bending area BA of the display device according to an example embodiment of the present specification, a groove G can be formed on the first substrate PI1.

In other words, the first substrate PI1 can be formed to have a first thickness d1 in the display area DA and the non-display area NA, and can be formed to have a second thickness d2 in the bending area BA where the groove G is formed.

Accordingly, in the embodiment of (b) of FIG. 16, the neutral plane in the bending area BA is elevated in the Z direction compared to the comparative example, and can be positioned on the wiring 200 instead of the substrate PI.

In addition, the groove G formed in the second substrate PI2 in the bending area BA can be formed in a tapered shape and can be formed equal to a width of the bending area BA or larger than the bending area BA.

Referring to (c) of FIG. 16, the bending area BA of the display device according to the embodiment of the present specification can be disposed with a substrate PI, a wiring 200 disposed on the substrate PI, a planarization layer PLN disposed on the wiring 200, and an insulating layer disposed on the planarization layer PLN. In addition, the bending area BA of the display device according to the embodiment of the present specification can further include a micro cover layer MCL disposed on the insulating layer. Here, the insulating layer can be formed of at least one of a bank BNK and a spacer SPC.

As shown in (b) of FIG. 16, the neutral plane according to the embodiment of the present specification, which is spaced apart from the center of the wiring 200 in the Z direction, is positioned on the wiring 200 by adjusting a position of the insulating layer.

For example, the neutral plane according to the embodiment of the present specification is moved toward the wiring 200 by the insulating layer such that no stress is applied to the wiring 200 or relatively little stress is applied. Furthermore, the position of the neutral plane can be adjusted closer to the center of the wiring 200 by the micro cover layer MCL disposed on the insulating layer. Here, the wiring 200 includes data lines DL and gate lines GL, and since the insulating layer is disposed on the wiring 200 as shown in FIG. 13, the movement principle with respect to the neutral plane can be applied to both the data lines DL and the gate lines GL.

In addition, since the plurality of insulating layers are spaced apart from each other, development of cracks can be prevented or reduced. In detail, even if a crack occurs in any one of the insulating layers, it is possible to prevent or reduce the development of cracks through the disposition structure in which they are spaced apart from each other.

Referring to (d) of FIG. 16, in the non-display area NA of the display device according to the embodiment of the present specification, the substrate PI can be formed in a single layer structure.

In other words, the substrate PI is formed in a double layer structure having the first and second substrates PI1 and PI2 and an inorganic film IPD between the first and second substrates PI1 and PI2 in the display area DA, and is formed in a single-layered structure including only the second substrate PI2 in the non-display area NA, such that the position of the neutral plane can be adjusted in the non-display area NA.

Accordingly, the neutral plane in the non-display area NA is positioned on the wiring 200, and thus, stresses due to bending of the display panel 100 can be reduced from being applied to the wirings 200.

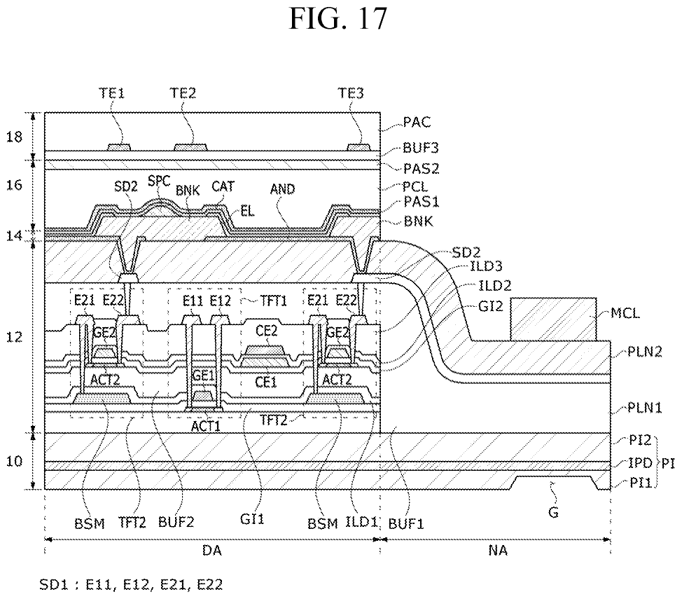

FIG. 17 is a diagram illustrating a cross-sectional structure of a display area in a display device according to another example embodiment of the present specification.

Since the description of the cross-sectional structure described in FIG. 15 can be applied to FIG. 17 as it is, the redundant descriptions will be omitted or can be briefly provided and added configurations will be described or clarified.

Referring to FIG. 17, a fifth metal layer is formed on the first planarization layer PLN1. The fifth metal layer is insulated from the fourth metal layer by the first planarization layer PLN1. The fifth metal layer includes a single metal layer patterned in a photolithography process or metal patterns in which two or more metal layers are stacked. The fifth metal layer includes a metal pattern SD2 connecting the light emitting element EL to the second TFT TFT2. The metal pattern SD2 is connected to the second electrode E22 of the second TFT TFT2 through a fourth contact hole penetrating the first planarization layer PLN1.

Although the metal pattern SD2 is illustrated as being connected to the second electrode E22 of the second TFT TFT2 in FIG. 17, it is not limited thereto. For example, according to a design, the metal pattern SD2 can be connected to the second electrode E12 of the first TFT TFT1, or can be connected to both the second electrode E12 of the first TFT TFT1 and the second electrode E22 of the second TFT TFT2.

A second planarization layer PLN2 is formed on the first planarization layer PLN1 to cover the metal patterns of the fifth metal layer. The second planarization layer PLN2 is an organic insulating material and thickly covers the display area DA of the circuit layer 12. A sixth metal layer is formed on the second planarization layer PLN2. The second planarization layer PLN2 flattens the surface on which the sixth metal layer is formed.

The sixth metal layer includes a single metal layer patterned in a photolithography process or metal patterns in which two or more metal layers are stacked. The pattern of the sixth metal layer includes an anode electrode AND of the light emitting element EL. The anode electrode AND is in contact with the metal pattern SD2 connected to the first TFT TFT1 or the second TFT TFT2 of the pixel circuits through the fifth contact hole penetrating the second planarization layer PLN2.

The wiring formed on the substrate PI in the bending area BA is formed of the same material as the metal pattern SD2 connecting the light emitting element EL of the display area DA to the first TFT TFT1 or the second TFT TFT2 and can be electrically connected to at least some of them.

In the light emitting element layer 14, the bank BNK is formed on the second planarization layer PLN2 to cover an edge of the anode electrode AND.

The display device of the present specification according to FIG. 17 can further include a second planarization layer PLN2 disposed to cover the wiring. Further, since the plurality of wirings formed on the bending area BA are formed on the first planarization layer PLN1, cracks in the wirings that can occur due to uneven surface of the substrate PI can be further improved.

A brief description of the embodiments of the present specification described above is as follows.

A display device according to embodiments of the present specification can include a substrate including a display area, a non-display area extended from the display area, and a bending area included in the non-display area, a plurality of wirings formed on (in) the bending area, and a micro cover layer formed on the plurality of wirings, wherein and a groove can be formed on the substrate to be overlapped with the bending area.

The display device according to the embodiments of the present specification can include a plurality of transistors formed on the substrate, a light emitting element electrically connected to at least one of the plurality of transistors, and a bank configured to define a light emitting area of the light emitting element.

In the display device according to the embodiments of the present specification, the substrate can have a first thickness in the display area and a second thickness in the bending area.

In the display device according to the embodiments of the present specification, the substrate can be formed in a double-layer structure and formed in the bending area in a single-layer form.

In the display device according to the embodiments of the present specification, the substrate can be formed in the display area in a double-layer structure and formed in the non-display area in a single-layer structure.

In the display device according to the embodiments of the present specification, a width of the groove can be equal to or greater than a width of the bending area.

In the display device according to the embodiments of the present specification, the display device can further include an insulating layer formed between the plurality of wirings and the micro cover layer in the bending area.

In the display device according to the embodiments of the present specification, the insulating layer can be formed of the bank.

In the display device according to the embodiments of the present specification, the insulating layer can further include a spacer on the bank.

In the display device according to embodiments of the present specification, the groove can have a tapered shape.

In the display device according to the embodiments of the present specification, the display device can further include a planarization layer formed on (in) the bending area to cover the plurality of wirings, wherein the planarization layer is formed to be extended from the display area.

In the display device according to the embodiments of the present specification, the display device can further include a micro cover layer formed on the planarization layer in the bending area.

In the display device according to the embodiments of the present specification, the plurality of wirings formed on (in) the bending area can be formed of the same metal layer as the source electrode or the drain electrode of the transistor formed in the display area.

In the display device according to the embodiments of the present specification, the plurality of wirings formed on (in) the bending area are formed of the same metal layer as a connection electrode formed in the display area.

A display device according to embodiments of the present specification can include a substrate including a display area, a non-display area extended from the display area, and a bending area included in the non-display area, a plurality of wirings formed on (in) the bending area, and a groove formed to be overlapped with the bending area in the substrate, wherein a neutral plane of the bending area is positioned close to the center of the wiring by the groove disposed to be overlapped with a partial area of the wiring.

The objects to be achieved by the embodiments of the present specification, the means for achieving the objects, and effects of the embodiments of the present specification described above do not specify essential features of the claims. Thus, the scope of the claims is not limited to the embodiments of the present specification.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area and a non-display area adjacent to the display area, the non-display area including a bending area;
a plurality of wirings formed in the bending area; and
a micro cover layer formed on the plurality of wirings,
wherein a groove is formed on the substrate and overlapped with the micro cover layer.

2. The display device according to claim 1, wherein the plurality of wirings are formed between the groove and the micro cover layer.

3. The display device according to claim 1, wherein each of the groove and the micro cover layer is overlapped with the plurality of wirings.

4. The display device according to claim 1, wherein at least one of the groove and the micro cover layer is formed in an island shape.

5. The display device according to claim 1, wherein the display area includes:
a plurality of transistors formed on the substrate;
a light emitting element electrically connected to at least one of the plurality of transistors; and
a bank configured to define a light emitting area of the light emitting element.

6. The display device according to claim 1, wherein the substrate has a first thickness in the display area and a second thickness in the bending area.

7. The display device according to claim 1, wherein the substrate is formed in a double-layer structure and formed in the bending area in a single-layer form.

8. The display device according to claim 1, wherein the substrate is formed in the display area in a double-layer structure and formed in the non-display area in a single-layer structure.

9. The display device according to claim 1, wherein a width of the groove is equal to or greater than a width of the bending area.

10. The display device according to claim 5, further comprising an insulating layer formed between the plurality of wirings and the micro cover layer in the bending area.

11. The display device according to claim 10, wherein the insulating layer and the bank include a same material.

12. The display device according to claim 11, wherein the insulating layer further includes a spacer on the bank.

13. The display device according to claim 1, wherein the groove has a tapered shape.

14. The display device according to claim 1, further comprising a planarization layer formed in the bending area to cover the plurality of wirings,
wherein the planarization layer extends from the display area.

15. The display device according to claim 14, further comprising a micro cover layer formed on the planarization layer in the bending area.

16. The display device according to claim 5, wherein the plurality of wirings formed in the bending area are formed of a same metal layer as a source electrode or a drain electrode of one of the plurality of transistors formed in the display area.

17. The display device according to claim 5, wherein the plurality of wirings formed in the bending area are formed of a same metal layer as a connection electrode formed in the display area.

18. A display device comprising:
a substrate including a display area and a non-display area adjacent to the display area, the non-display area including a bending area;
at least one wiring formed in the bending area; and
a groove formed to be overlapped with the bending area of the substrate,
wherein a neutral plane of the bending area is positioned close to a center of the at least one wiring by the groove disposed to be overlapped with a partial area of the at least one wiring.
